(19) United States
(12) Patent Application Publication
(10) Pub. No.: US 2019/0373752 A1
(43) Pub. Date: Dec. 5, 2019

(54) PLUG-IN UNIT AND ELECTRONIC DEVICE

(71) Applicant: FUJITSU LIMITED, Kawasaki-shi (JP)

(72) Inventor: Kenji JOKO, Yokohama (JP)

(73) Assignee: FUJITSU LIMITED, Kawasaki-shi (JP)

(21) Appl. No.: 16/413,089

(22) Filed: May 15, 2019

(30) Foreign Application Priority Data
Jun. 1, 2018 (JP) 2018-106539

(51) Int. Cl. H05K 7/10; H05K 7/14

(52) U.S. Cl. CPC H05K 7/10; H05K 7/1401; H05K 7/1487

(57) ABSTRACT

A plug-in unit includes a housing that includes a front surface plate, a lever member, when the housing has been inserted into the other housing, that is rotated, in response to an operation by an operator, so as to apply a force to the housing in a direction in which the housing is removed, a lock member that is slidably provided in the lever member and, when the housing has been inserted into the other housing, that is engaged with an engagement hole formed in the front surface plate, thereby locking the lever member so as to inhibit the rotation of the lever member, and a rotation regulating mechanism that temporarily regulates the rotation of the lever member in accordance with sliding of the lock member in a direction in which the engagement between the lock member and the engagement hole of the front surface plate is released.

### CROSS-REFERENCE TO RELATED APPLICATION

This application is based upon and claims the benefit of priority of the prior Japanese Patent Application No. 2018-106539, filed on Jun. 1, 2018, the entire contents of which are incorporated herein by reference.

### FIELD

The embodiments discussed herein are related to a plug-in unit and an electronic device.

### BACKGROUND

In an electronic device such as blade-type server device, for example, a plug-in unit (PIU) is inserted into and removed from the electronic device by using a lever member rotatably provided in the PIU. The lever member rotatably provided in the PIU has the function of a lever. That is, when inserting the PIU into the electronic device, the lever member is rotated, due to operation by an operator, in the direction in which the lever member approaches a front surface plate of the PIU, thereby a force is applied due to an action of the lever to the PIU through the lever member in the direction in which the PIU is inserted. When inserted into the electronic device, the PIU is electrically connected to a board of the electronic device. In contrast, when removing the PIU from the electronic device, the lever member is rotated, due to the operation by the operator, in the direction in which the lever member is separated from the front surface plate of the PIU, thereby a force is applied due to an action of the lever to the PIU through the lever member in the direction in which the PIU is removed.

Related art is disclosed in, for example, Japanese Laid-open Patent Publication Nos. 5-259662 and 2011-254052 and so forth.

In the PIU, a lock member that locks the lever member so as to prohibit the rotation of the lever member is provided such that the lock member is slidable relative to the lever member. The lock member is, when the PIU has been inserted into the electronic device, engaged with an engagement hole formed in the front surface plate of the PIU, thereby locking the lever member so as to inhibit the rotation of the lever member. When removing the PIU from the electronic device, first, the lock member is slid relative to the lever member so as to release the engagement between the lock member and the engagement hole of the front surface plate. Then, the lever member is rotated due to the operation by the operator so as to apply a force to the PIU, through the lever member, in the direction in which the PIU is removed.

However, when the lever member is operated immediately after the engagement between the lock member and the engagement hole of the front surface plate has been released, in some cases the PIU is removed from the electronic device before the completion of communication for interrupting the electrical connection between the PIU and the board in the electronic device. When the PIU is removed from the electronic device before the completion of the communication for interrupting the electrical connection between the PIU and the board in the electronic device, a communication error may occur on the electronic device side because the electronic device still accesses the PIU. Thus, temporary regulation of the operation of the lever member while removing the PIU is expected.

In view of the above description, it is desired to provide a plug-in unit and an electronic device that allows, in view of the above description, operation of a lever member to be temporarily regulated while removing the plug-in unit.

### SUMMARY

According to an aspect of the embodiments, a plug-in unit includes a housing that includes a front surface plate and that is removably insertable into another housing, a lever member that is rotatably provided in the housing and, when the housing has been inserted into the other housing, that is rotated, in response to an operation by an operator, so as to apply a force to the housing in a direction in which the housing is removed, a lock member that is slidably provided in the lever member and, when the housing has been inserted into the other housing, that is engaged with an engagement hole formed in the front surface plate, thereby locking the lever member so as to inhibit the rotation of the lever member, and a rotation regulating mechanism that temporarily regulates the rotation of the lever member in accordance with sliding of the lock member in a direction in which the engagement between the lock member and the engagement hole of the front surface plate is released.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view of an example of an external structure of an electronic device according to a first embodiment;

FIG. 2 is a perspective view of an example of an external structure of a plug-in unit (PIU) according to the first embodiment;

FIG. 3 is a perspective view of an example of an internal structure of the PIU according to the first embodiment;

FIG. 4 is a plan view of the example of the internal structure of the PIU according to the first embodiment;

FIG. 5 is a flowchart of an example of a method of removing the PIU according to the first embodiment;

FIG. 6 illustrates the example of the method of removing the PIU according to the first embodiment;

FIG. 7 illustrates the example of the method of removing the PIU according to the first embodiment;

FIG. 8 illustrates the example of the method of removing the PIU according to the first embodiment;

FIG. 9 is a perspective view of an example of an internal structure of the PIU according to a second embodiment;

FIG. 10 is a plan view of the example of the internal structure of the PIU according to the second embodiment;

FIG. 11 is a perspective view of an example of an internal structure of the PIU according to a third embodiment; and

FIG. 12 is a plan view of the example of the internal structure of the PIU according to the third embodiment.

### DESCRIPTION OF EMBODIMENTS

Embodiments of an electronic device disclosed herein will be described in detail below with reference to the drawings. These embodiments do not limit disclosed techniques.

[First Embodiment]

[Structure of an Electronic Device 1]

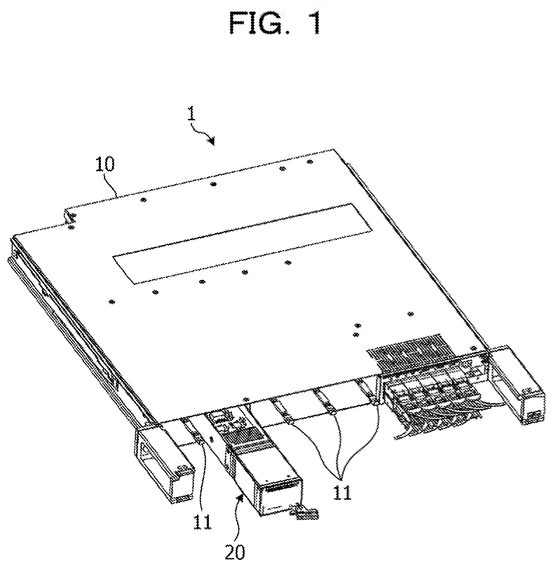

FIG. 1 is a perspective view of an example of an external structure of an electronic device 1 according to a first embodiment. The electronic device 1 illustrated in FIG. 1 is, for example, a blade-type server device or the like removably mountable in a rack (not illustrated). The electronic device 1 includes a housing 10. The housing 10 is a box having a bottom plate, a top plate facing the bottom plate, a pair of side walls facing each other, a front surface, and a rear surface. In FIG. 1, out of surfaces of the housing 10, a surface on the front side of the page of the drawing is the front surface of the housing 10 and a surface on the rear side of the page of the drawing is the rear surface of the housing 10. A board (not illustrated) that is a printed circuit board is contained in the housing 10. A plurality of slots are formed in the front surface of the housing 10. The slots in the front surface of the housing 10 are separated from one another by rails 11 provided on the bottom plate of the housing 10. Plug-in units (PIUs) 20 are inserted along the rails 11 into the slots in the front surface of the housing 10. Thus, each of the PIUs 20 is electrically connected to circuitry printed on the board in the housing 10.

[Structure of the PIU 20]

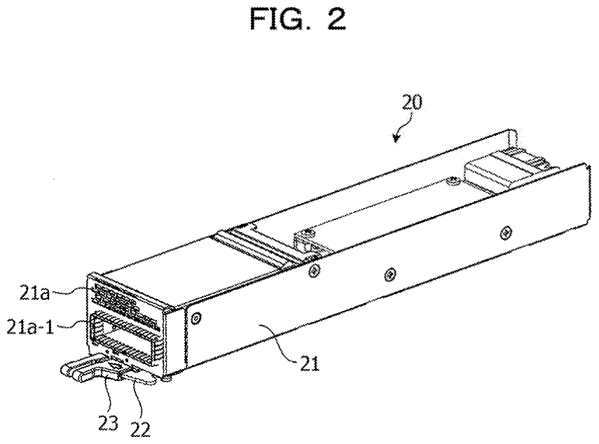

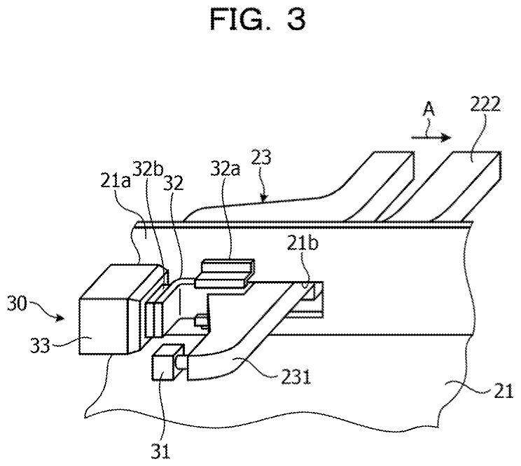

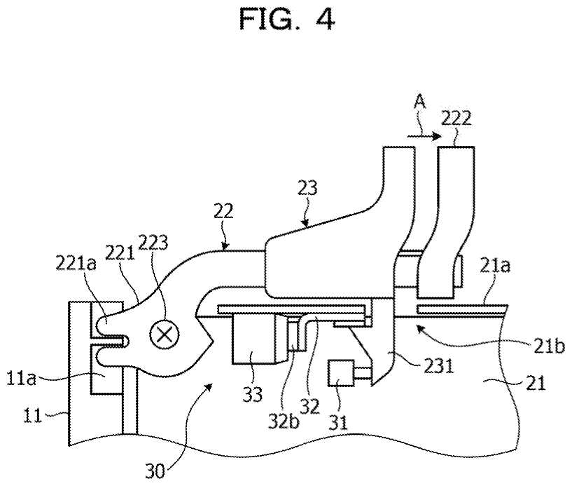

FIG. 2 is a perspective view of an example of an external structure of the PIU 20 according to the first embodiment. FIG. 3 is a perspective view of an example of an internal structure of the PIU 20 according to the first embodiment. FIG. 4 is a plan view of the example of the internal structure of the PIU 20 according to the first embodiment. In FIG. 2, the front side of the page of the drawing corresponds to the front surface side of the housing 10. In FIG. 3, the rear side of the page of the drawing corresponds to the front surface side of the housing 10. In FIG. 4, the upper side of the page of the drawing corresponds to the front surface side of the housing 10.

As illustrated in FIGS. 2 to 4, the PIU 20 includes a housing 21 removably mountable to the housing 10, a lever member 22, and a lock member 23. The housing 21 has a front surface plate 21a. The front surface plate 21a has an opening 21a-1. A pluggable optical module that transmits and receives optical signals is inserted into the opening 21a-1.

The lever member 22 is rotatably provided in the housing 21 and operated by an operator when the PIU 20 is inserted into or removed from the housing 10. The lever member 22 is also referred to as a “card lever”. The lever member 22 has a function of a lever. Specifically, a proximal end portion 221 of the lever member 22 is rotatably supported by a rotating shaft 223 that is provided on the bottom plate of the housing 21 and serves as the fulcrum of the lever. A distal end portion 222 of the lever member 22 forms the point of effort of the lever subjected to a force based on the operation by the operator. A projecting portion 221a is formed in the proximal end portion 221 of the lever member 22. The projecting portion 221a is engaged with grooves 11a of a corresponding one of the rails 11 provided in the housing 10 so as to form the point of application of the lever.

When inserting the PIU 20 into the housing 10, the lever member 22 is rotated, due to the operation by the operator, in the direction in which the lever member 22 approaches the front surface plate 21a of the housing 21, thereby a force is applied due to an action of the lever to the housing 21 through the lever member 22 in the direction in which the PIU 20 is inserted. Thus, the PIU 20 (that is, the housing 21) is inserted into the housing 10. In contrast, when removing the PIU 20 from the housing 10, the lever member 22 is rotated, due to the operation by the operator, in the direction in which the lever member 22 is separated from the front surface plate 21a of the housing 21, thereby a force is applied due to an action of the lever to the housing 21 through the lever member 22 in the direction in which the PIU 20 is removed. Thus, the PIU 20 (that is, the housing 21) is removed from the housing 10.

The lock member 23 is slidably provided in the lever member 22. The lock member 23 is, when the housing 21 has been inserted into the housing 10, engaged with an engagement hole 21b formed in the front surface plate 21a of the housing 21, thereby locking the lever member 22 so as to inhibit the rotation of the lever member 22. Specifically, the lock member 23 includes a hook portion 231. The lock member 23 causes the hook portion 231 having been inserted through the engagement hole 21b of the front surface plate 21a to be hooked onto a rear surface of the front surface plate 21a with a slide plate 32 interposed therebetween. Thus, the lock member 23 locks the lever member 22 so as to inhibit the rotation of the lever member 22. An urging member (not illustrated) is inserted between the lock member 23 and the distal end portion 222 of the lever member 22. The lock member 23 is urged, by an urging force applied by the urging member, in the opposite direction of an arrow A (referred to as a “direction A” hereinafter). The engagement between the lock member 23 and the engagement hole 21b of the front surface plate 21a is able to be released when the lock member 23 is slid in the direction A against the urging force of the urging member. The direction A is an example of a direction in which the engagement between the lock member 23 and the engagement hole 21b of the front surface plate 21a is released.

As illustrated in FIGS. 3 and 4, the PIU 20 includes a rotation regulating mechanism 30 disposed in the housing 21. The rotation regulating mechanism 30 temporarily regulates the rotation of the lever member 22 in accordance with sliding of the lock member 23 in the direction A in which the engagement between the lock member 23 and the engagement hole 21b of the front surface plate 21a is released. The rotation regulating mechanism 30 includes a detector 31, the slide plate 32, and an electromagnet 33. The detector 31 and the electromagnet 33 are connected to a control circuit (not illustrated).

The detector 31 detects the sliding of the lock member 23 in the direction A in which the engagement between the lock member 23 and the engagement hole 21b of the front surface plate 21a is released. For example, the detector 31 is a contact switch that outputs an ON signal to the control circuit when the detector 31 and the lock member 23 are in contact with each other and that stops the output of the ON signal to the control circuit when the lock member 23 is slid in the direction A and separated from the detector 31. The control circuit monitors the sliding of the lock member 23 in the direction A by determining whether the output of the ON signal from the detector 31 is absent or present.

The slide plate 32 is slidably mounted to the front surface plate 21a with a slide rail 32a secured to the front surface plate 21a interposed therebetween. Part of the slide plate 32 is bent so as to face the electromagnet 33. A permanent magnet 32b is mounted on the bent part of the slide plate 32.

The electromagnet 33 is secured to the front surface plate 21a so as to face the part (that is, the permanent magnet 32b) of the slide plate 32. While the sliding of the lock member 23 is not detected by the detector 31, the electromagnet 33 is kept turned OFF and attracts the permanent magnet 32b to the core thereof so as to hold the slide plate 32 at an initial position where the engagement hole 21b of the front surface plate 21a is unblocked. When the sliding of the lock member 23 is detected by the detector 31, the control circuit causes the electromagnet 33 to be turned ON so as to generate a magnetic force against a magnetic force of the permanent magnet 32b. Thus, the electromagnet 33 causes, by using the magnetic force against the magnetic force of the permanent magnet 32b, the slide plate 32 to temporarily slide in the direction in which the slide plate 32 blocks the engagement hole 21b of the front surface plate 21a, thereby causing the slide plate 32 to interfere with the lock member 23. This temporarily obstructs releasing of the engagement between the lock member 23 and the engagement hole 21b of the front surface plate 21a.

Meanwhile, in the electronic device 1, communication for interrupting electrical connection between the PIU 20 and the board in the housing 10 is performed in a time period from when the engagement between the lock member 23 and the engagement hole 21b of the front surface plate 21a is released to when the lever member 22 is operated. For example, the board in the housing 10 accesses the PIU 20 to transmit a stop command for stopping the electrical connection in the time period from when the engagement between the lock member 23 and the engagement hole 21b of the front surface plate 21a is released to when the lever member 22 is operated. A processing time period required to transmit the stop command, that is, a processing time period required for the communication for interrupting the electrical connection between the PIU 20 and the board in the housing 10 is about a few to several seconds.

However, when the lever member 22 is operated immediately after the engagement between the lock member 23 and the engagement hole 21b of the front surface plate 21a has been released, the PIU 20 is removed from the housing 10 before the completion of the communication for interrupting the electrical connection between the PIU 20 and the board in the housing 10. When the PIU 20 is removed from the housing 10 before the completion of the communication for interrupting the electrical connection between the PIU 20 and the board in the housing 10, a communication error may occur on the board in the housing 10 side because the housing 10 still accesses the PIU 20.

Accordingly, in the electronic device 1, the rotation regulating mechanism 30 temporarily regulates the rotation of the lever member 22 in accordance with the sliding of the lock member 23 in the direction A in which the engagement between the lock member 23 and the engagement hole 21b of the front surface plate 21a is released.

Thus, even when the lock member 23 is slid in the direction A in which the engagement between the lock member 23 and the engagement hole 21b of the front surface plate 21a is released, the rotation of the lever member 22 is temporarily regulated. This allows the electronic device 1 to temporarily regulate the operation of the lever member 22 while removing the PIU 20. Consequently, the occurrence of a situation in which the lever member 22 is operated immediately after the engagement between the lock member 23 and the engagement hole 21b of the front surface plate 21a has been released may be avoided, and accordingly, the occurrence of a communication error may be suppressed.

[A Method of Removing the PIU 20 from the Housing 10]

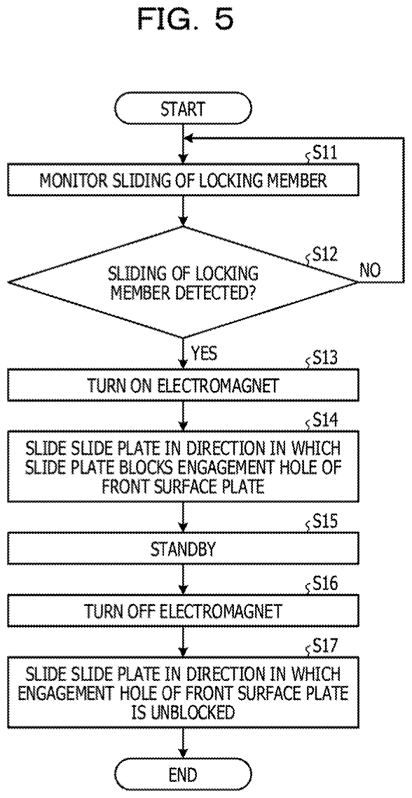

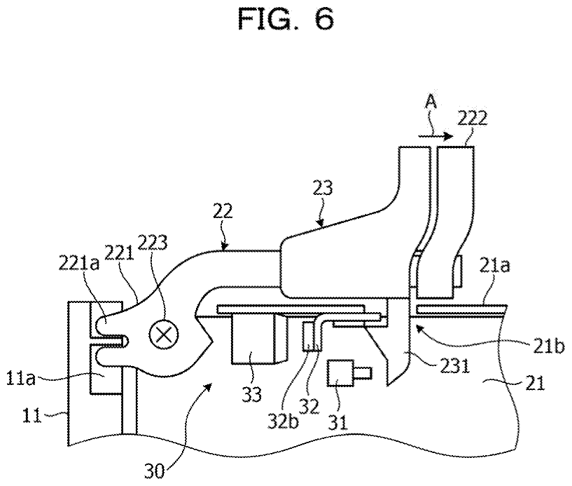

Next, a method of removing the PIU 20 from the housing 10 is described. FIG. 5 is a flowchart of an example of the method of removing the PIU 20 according to the first embodiment. FIGS. 6 to 8 illustrate the example of the method of removing the PIU 20 according to the first embodiment. In the initial state, the PIU 20 (that is, the housing 21) is assumed to be inserted into the housing 10, and the lock member 23 is, as illustrated in FIG. 4, assumed to be engaged with the engagement hole 21b of the front surface plate 21a of the housing 21 so as to lock the lock lever member 22 so as to inhibit the rotation of the lever member 22.

As illustrated in FIG. 5, whether the output of the ON signal from the detector 31 is absent or present is determined by the control circuit connected to the detector 31, thereby sliding of the lock member 23 in the direction A is monitored (step S11). When the sliding of the lock member 23 in the direction A is not detected by the detector 31, that is, the ON signal from the detector 31 to the control circuit is output (“No” in step S12), processing returns to step S11 and the control circuit continues the monitoring.

When the sliding of the lock member 23 in the direction A is detected by the detector 31, that is, the output of the ON signal from the detector 31 to the control circuit is stopped (“Yes” in step S12), the control circuit causes the electromagnet 33 to be turned ON (step S13). The electromagnet 33 having been turned ON generates the magnetic force against the magnetic force of the permanent magnet 32b mounted on the part of the slide plate 32. Since the electromagnet 33 and the permanent magnet 32b repel each other, the slide plate 32 slides, from the initial position (see FIG. 4) where the engagement hole 21b of the front surface plate 21a is unblocked, in the direction in which the slide plate 32 blocks the engagement hole 21b of the front surface plate 21a as illustrated in FIG. 6 and step S14. This causes the slide plate 32 to interfere with the hook portion 231 of the lock member 23 as illustrated in FIG. 6.

Next, the control circuit puts the PIU 20 on standby for a predetermined period of time with the electromagnet 33 kept turned ON (step S15). This temporarily obstructs releasing of the engagement between the lock member 23 and the engagement hole 21b of the front surface plate 21a. The predetermined period of time of the standby put by the control circuit is appropriately adjusted to a period of time with which the completion of the communication for interrupting the electrical connection between the PIU 20 and the board in the housing 10 is allowed.

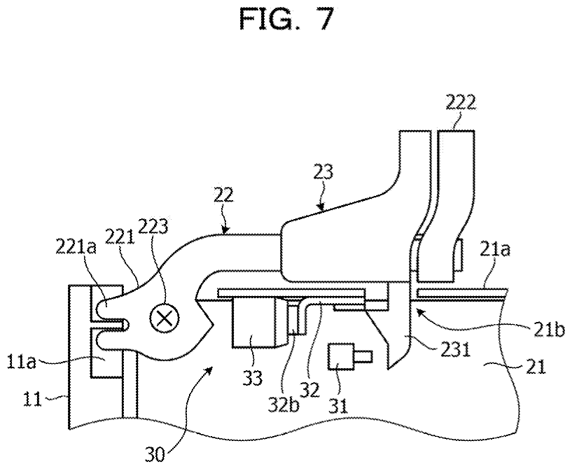

After the elapse of the predetermined period of time, the control circuit causes the electromagnet 33 to be turned OFF (step S16). When the permanent magnet 32b mounted on the part of the slide plate 32 is attracted to the core of the electromagnet 33 having been turned OFF, the slide plate 32 slides in the direction in which the engagement hole 21b of the front surface plate 21a is unblocked as illustrated in FIG. 7 and step S17. This causes the slide plate 32 to be removed from the hook portion 231 of the lock member 23 as illustrated in FIG. 7. Thus, the engagement between the lock member 23 and the engagement hole 21b of the front surface plate 21a is released, and the locking of the lever member 22 by the lock member 23 so as to inhibit the rotation of the lever member 22 is released.

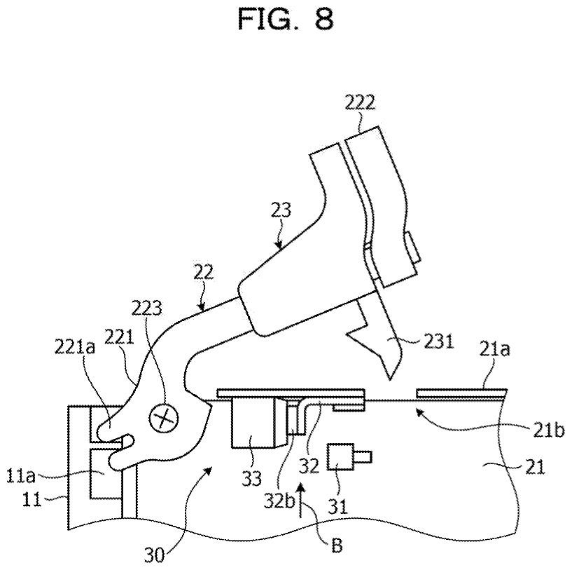

Then, as illustrated in FIG. 8, the lever member 22 is rotated, due to the operation by the operator, in the direction in which the lever member 22 is separated from the front surface plate 21a of the housing 21, thereby a force is applied, due to an action of the lever, to the housing 21 through the lever member 22 in the direction in which the PIU 20 is removed (direction indicated by an arrow B). Thus, the PIU 20 (that is, the housing 21) is removed from the housing 10.

As has been described, the PIU 20 according to the first embodiment includes the housing 21, the lever member 22, the lock member 23, and the rotation regulating mechanism 30. The housing 21 includes the front surface plate 21a and is removably mountable to the housing 10 of the electronic device 1. The lever member 22 is rotatably provided in the housing 21 and, when the housing 21 has been inserted into the housing 10, rotated, in response to the operation by the operator, so as to apply a force to the housing 21 in the direction in which the housing 21 is removed. The lock member 23 is slidably provided in the lever member 22 and, when the housing 21 has been inserted into the housing 10, engaged with the engagement hole 21b formed in the front surface plate 21a, thereby locking the lever member 22 so as to inhibit the rotation of the lever member 22. The rotation regulating mechanism 30 temporarily regulates the rotation of the lever member 22 in accordance with the sliding of the lock member 23 in the direction A in which the engagement between the lock member 23 and the engagement hole 21b of the front surface plate 21a is released.

With the PIU 20 having the above-described structure, even when the lock member 23 slides in the direction A in which the engagement between the lock member 23 and the engagement hole 21b of the front surface plate 21a is released, the rotation of the lever member 22 is temporarily regulated. This allows the electronic device 1 to temporarily regulate the operation of the lever member 22 while removing the PIU 20. Consequently, the occurrence of a situation in which the lever member 22 is operated immediately after the engagement between the lock member 23 and the engagement hole 21b of the front surface plate 21a has been released may be avoided, and accordingly, the occurrence of a communication error may be suppressed.

In the PIU 20 according to the first embodiment, the rotation regulating mechanism 30 includes the detector 31, the slide plate 32, and the electromagnet 33. The detector 31 detects the sliding of the lock member 23 in the direction A in which the engagement between the lock member 23 and the engagement hole 21b of the front surface plate 21a is released. The slide plate 32 is slidably mounted to the front surface plate 21a. The electromagnet 33 is secured to the front surface plate 21a so as to face the part of the slide plate 32 and, when the sliding of the lock member 23 is detected, causes, by using the magnetic force, the slide plate 32 to temporarily slide in the direction in which the slide plate 32 blocks the engagement hole 21b of the front surface plate 21a, thereby the electromagnet 33 obstructs releasing of the engagement.

With the above-described structure of the PIU 20, locking of the lever member 22 with the lock member 23 so as to inhibit the rotation of the lever member 22 is able to be temporarily maintained. This allows the electronic device 1 to temporarily regulate the operation of the lever member 22 while removing the PIU 20 due to locking of the lever member 22 with the lock member 23 so as to inhibit the rotation of the lever member 22.

[Second Embodiment]

The PIU 20 according to a second embodiment has a similar structure to the structure of the PIU 20 according to the first embodiment other than that the lock member 23 is provided with an engagement claw that pulls the slide plate 32 in accordance with the sliding of the lock member 23. Accordingly, for the second embodiment, elements common to the first embodiment and the second embodiment are denoted by the same reference signs and detailed description thereof is omitted.

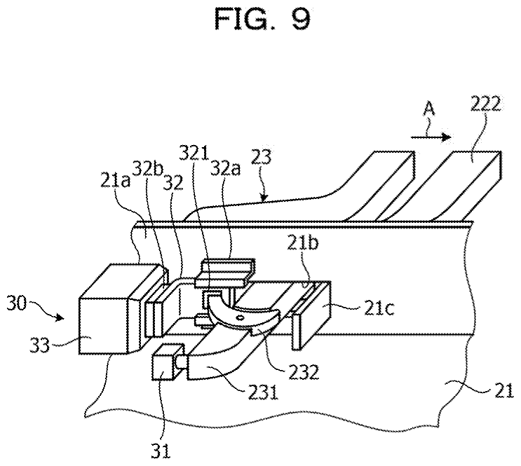

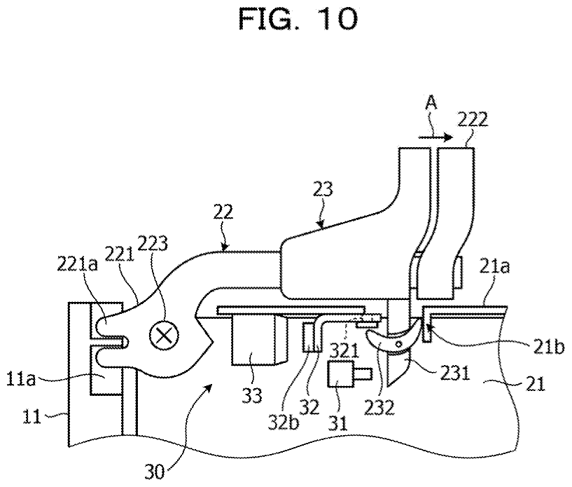

FIG. 9 is a perspective view of an example of an internal structure of the PIU 20 according to the second embodiment. FIG. 10 is a plan view of the example of the internal structure of the PIU 20 according to the second embodiment. In FIG. 9, the rear side of the page of the drawing corresponds to the front surface side of the housing 10. In FIG. 10, the upper side of the page of the drawing corresponds to the front surface side of the housing 10.

As illustrated in FIGS. 9 and 10, in the PIU 20 according to the second embodiment, the lock member 23 includes an engagement claw 232.

The engagement claw 232 is rotatably provided in the lock member 23 (hook portion 231). As the lock member 23 and the engagement hole 21b of the front surface plate 21a are brought into engagement with each other, the engagement claw 232 is rotated so as to be brought into engagement with an engagement hole 321 formed in the slide plate 32. An urging member (not illustrated) is disposed between the engagement claw 232 and the hook portion 231 of the lock member 23 so as to urge the engagement claw 232 toward the engagement hole 321 of the slide plate 32 with an urging force thereof. The engagement claw 232 pulls the slide plate 32 in the direction in which the slide plate 32 blocks the engagement hole 21b of the front surface plate 21a in accordance with the sliding of the lock member 23 in the direction A. Specifically, pulling the slide plate 32 by the engagement claw 232 in the direction in which the slide plate 32 blocks the engagement hole 21b of the front surface plate 21a assists the sliding of the slide plate 32 based on the fact that the electromagnet 33 and the permanent magnet 32b repel each other. When the engagement claw 232 is brought into contact with a wall 21c formed in proximity to the engagement hole 21b of the front surface plate 21a, the engagement claw 232 is rotated against the urging force of the urging member so as to be moved out of the engagement hole 321 of the slide plate 32. FIG. 10 illustrates a state of the engagement claw 232 having been moved out of the engagement hole 321 of the slide plate 32.

As has been described, in the PIU 20 according to the second embodiment, the lock member 23 includes the engagement claw 232. The engagement claw 232 is rotatably provided in the lock member 23, and, as the lock member 23 and the engagement hole 21b of the front surface plate 21a are brought into engagement with each other, rotated so as to be brought into engagement with the engagement hole 321 formed in the slide plate 32. The engagement claw 232 pulls the slide plate 32 in the direction in which the slide plate 32 blocks the engagement hole 21b of the front surface plate 21a in accordance with the sliding of the lock member 23.

The above-described structure of the PIU 20 assists the sliding of the slide plate 32 based on the fact that the electromagnet 33 and the permanent magnet 32b repel each other. Thus, the slide plate 32 may stably interfere with the lock member 23. This may stably obstruct releasing of the engagement between the lock member 23 and the engagement hole 21b of the front surface plate 21a. As a result, locking of the lever member 22 with the lock member 23 so as to inhibit the rotation of the lever member 22 may be stably maintained.

[Third Embodiment]

The PIU 20 according to a third embodiment has a structure similar to the structure of the PIU 20 according to the first embodiment other than the structure of the rotation regulating mechanism. Accordingly, for the third embodiment, elements common to the first embodiment and the third embodiment are denoted by the same reference signs and detailed description thereof is omitted.

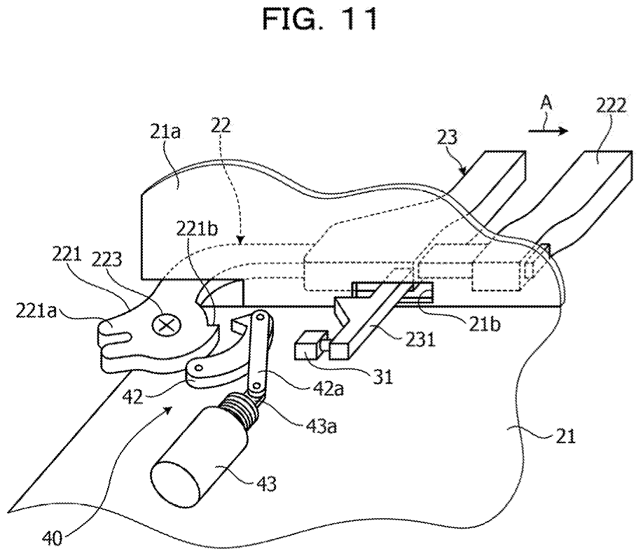

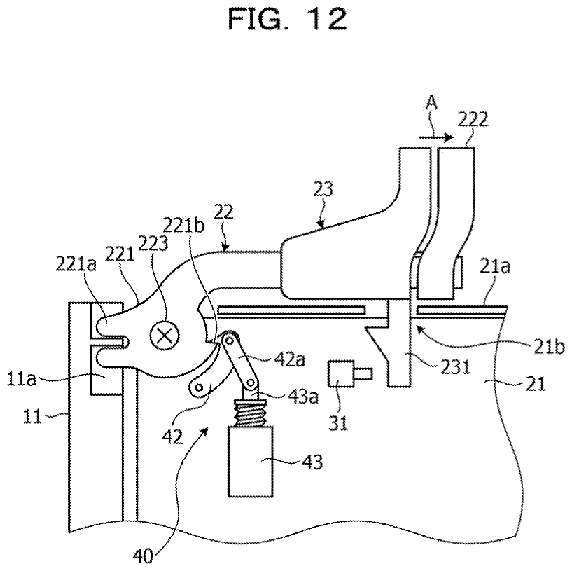

FIG. 11 is a perspective view of an example of an internal structure of the PIU 20 according to the third embodiment. FIG. 12 is a plan view of the example of the internal structure of the PIU 20 according to the third embodiment. In FIG. 11, the rear side of the page of the drawing corresponds to the front surface side of the housing 10. In FIG. 12, the upper side of the page of the drawing corresponds to the front surface side of the housing 10.

As illustrated in FIGS. 11 and 12, the PIU 20 according to the third embodiment includes a rotation regulating mechanism 40 instead of the rotation regulating mechanism 30. The rotation regulating mechanism 40 temporarily regulates the rotation of the lever member 22 in accordance with the sliding of the lock member 23 in the direction A in which the engagement between the lock member 23 and the engagement hole 21b of the front surface plate 21a is released. The rotation regulating mechanism 40 includes the detector 31, a hook member 42, and an actuator 43. The detector 31 and the actuator 43 are connected to the control circuit (not illustrated).

The hook member 42 is disposed in proximity to a projecting portion 221b formed in the lever member 22 (proximal end portion 221). A proximal end portion of the hook member 42 is rotatably supported at a rotation shaft provided in the bottom plate of the housing 21. A distal end portion of the hook member 42 is coupled to a rod 43a of the actuator 43 with a coupling member 42a interposed therebetween.

The actuator 43 is of a solenoid type and includes an electromagnet disposed therein for extension and contraction of the rod 43a by the magnetic force of the electromagnet. While the sliding of the lock member 23 is not detected by the detector 31, the actuator 43 is kept turned OFF. Thus, the rod 43a is contracted, and the hook member 42 is held at a retracted position where the hook member 42 is not hooked onto the projecting portion 221b of the lever member 22. When the sliding of the lock member 23 is detected by the detector 31, the control circuit causes the actuator 43 to be turned ON so as to extend the rod 43a. The actuator 43 causes the hook member 42, which is coupled to the rod 43a with the coupling member 42a interposed therebetween, to be rotated from the retracted position, thereby causing the hook member 42 to be temporarily hooked onto the projecting portion 221b of the lever member 22 so as to regulate the rotation of the lever member 22.

As has been described, in the PIU 20 according to the third embodiment, the rotation regulating mechanism 40 includes the detector 31, the hook member 42, and the actuator 43. The detector 31 detects the sliding of the lock member 23 in the direction A in which the engagement between the lock member 23 and the engagement hole 21b of the front surface plate 21a is released. The hook member 42 is disposed in proximity to the projecting portion 221b formed in the lever member 22. When the sliding of the lock member 23 is detected, the actuator 43, which is coupled to the hook member 42, causes the hook member 42 to be temporarily hooked onto the projecting portion 221b of the lever member 22 so as to regulate the rotation of the lever member 22.

With the PIU 20 having the above-described structure, even when the lock member 23 slides in the direction A in which the engagement between the lock member 23 and the engagement hole 21b of the front surface plate 21a is released, the rotation of the lever member 22 is temporarily regulated. This allows the electronic device 1 to temporarily regulate the operation of the lever member 22 while removing the PIU 20.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A plug-in unit comprising:
a housing that includes a front surface plate and that is removably insertable into another housing;
a lever member that is rotatably provided in the housing and, when the housing has been inserted into the other housing, that is rotated, in response to an operation by an operator, so as to apply a force to the housing in a direction in which the housing is removed;
a lock member that is slidably provided in the lever member and, when the housing has been inserted into the other housing, that is engaged with an engagement hole formed in the front surface plate, thereby locking the lever member so as to inhibit the rotation of the lever member; and
a rotation regulating mechanism that temporarily regulates the rotation of the lever member in accordance with sliding of the lock member in a direction in which the engagement between the lock member and the engagement hole of the front surface plate is released.

2. The plug-in unit according to claim 1, wherein
the rotation regulating mechanism includes
a detector that detects the sliding of the lock member in the direction in which the engagement between the lock member and the engagement hole of the front surface plate is released,
a slide plate slidably mounted to the front surface plate, and
an electromagnet that is secured to the front surface plate so as to face part of the slide plate and, when the sliding of the lock member is detected, that causes, by using the magnetic force, the slide plate to temporarily slide in a direction in which the slide plate blocks the engagement hole of the front surface plate, thereby obstructing releasing of the engagement.

3. The plug-in unit according to claim 2, wherein
the lock member includes an engagement claw that is rotatably provided in the lock member, that is, as the lock member and the engagement hole of the front surface plate are brought into engagement with each other, rotated so as to be brought into engagement with an engagement hole formed in the slide plate, and that pulls, in accordance with the sliding of the lock member, the slide plate in the direction in which the slide plate blocks the engagement hole of the front surface plate.

4. The plug-in unit according to claim 3, wherein
when the engagement claw is brought into contact with a wall formed in proximity to the engagement hole of the front surface plate, the engagement claw is rotated so as to be moved out of the engagement hole of the slide plate.

5. The plug-in unit according to claim 1, wherein
the rotation regulating mechanism includes
a detector that detects the sliding of the lock member in the direction in which the engagement between the lock member and the engagement hole of the front surface plate is released,
a hook member disposed in proximity to a projecting portion formed in the lever member, and
an actuator that is coupled to the hook member and, when the sliding of the lock member is detected, that causes the hook member to be temporarily hooked onto the projecting portion of the lever member so as to regulate the rotation of the lever member.

6. An electronic device comprising:
a first housing; and
a plug-in unit that is inserted into the first housing and that is electrically connected to a board in the first housing,
wherein the plug-in unit includes
a second housing that includes a front surface plate and that is removably insertable into the first housing,
a lever member that is rotatably provided in the second housing and, when the second housing has been inserted into the first housing, that is rotated in a direction in which a force in a direction in which the second housing is removed is applied to the second housing,
a lock member that is slidably provided in the lever member and, when the second housing has been inserted into the first housing, that is engaged with an engagement hole formed in the front surface plate, thereby locking the lever member so as to inhibit the rotation of the lever member, and
a rotation regulating mechanism that temporarily regulates the rotation of the lever member in accordance with sliding of the lock member in a direction in which the engagement between the lock member and the engagement hole of the front surface plate is released.

7. The plug-in unit according to claim 6, wherein
the rotation regulating mechanism includes
a detector that detects the sliding of the lock member in the direction in which the engagement between the lock member and the engagement hole of the front surface plate is released,
a slide plate slidably mounted to the front surface plate, and
an electromagnet that is secured to the front surface plate so as to face part of the slide plate and, when the sliding of the lock member is detected, that causes, by using the magnetic force, the slide plate to temporarily slide in a direction in which the slide plate blocks the engagement hole of the front surface plate, thereby obstructing releasing of the engagement.

8. The plug-in unit according to claim 7, wherein
the lock member includes an engagement claw that is rotatably provided in the lock member, that is, as the lock member and the engagement hole of the front surface plate are brought into engagement with each other, rotated so as to be brought into engagement with an engagement hole formed in the slide plate, and that pulls, in accordance with the sliding of the lock member, the slide plate in the direction in which the slide plate blocks the engagement hole of the front surface plate.

9. The plug-in unit according to claim 8, wherein
when the engagement claw is brought into contact with a wall formed in proximity to the engagement hole of the front surface plate, the engagement claw is rotated so as to be moved out of the engagement hole of the slide plate.

10. The plug-in unit according to claim 6, wherein
the rotation regulating mechanism includes
a detector that detects the sliding of the lock member in the direction in which the engagement between the lock member and the engagement hole of the front surface plate is released,
a hook member disposed in proximity to a projecting portion formed in the lever member, and
an actuator that is coupled to the hook member and, when the sliding of the lock member is detected, that causes the hook member to be temporarily hooked onto the projecting portion of the lever member so as to regulate the rotation of the lever member.
